(19) United States
(12) Patent Application Publication
(10) Pub. No.: US 2026/0196987 A1
(43) Pub. Date: Jul. 9, 2026

(54) OSCILLATOR AND OPERATION METHOD THEREOF

(71) Applicant: Realtek Semiconductor Corporation, Hsinchu (TW)

(72) Inventor: Chih Hsien WANG, Hsinchu (TW)

(21) Appl. No.: 19/428,322

(22) Filed: Dec. 22, 2025

(30) Foreign Application Priority Data
Jan. 3, 2025 (TW) 114100377

(51) Int. Cl. H03K 3/014

(52) U.S. Cl. CPC H03K 3/014

(57) ABSTRACT

An oscillator includes a logic circuit and an oscillation circuit. The logic circuit is configured to receive an enable signal and a feedback signal and generate a first control signal according to the enable signal and the feedback signal. The oscillation circuit is coupled to the logic circuit and is configured to generate the feedback signal and an oscillation output signal according to the first control signal.

### RELATED APPLICATIONS

This application claims priority to Taiwanese Application Serial Number 114100377, filed January 03, 2025, which is herein incorporated by reference.

### BACKGROUND

### Technical Field

The present disclosure relates to oscillator technology. More particularly, the present disclosure relates to an oscillator which can start quickly and has high reliability.

### Description of Related Art

With development of technology, various circuits are developed. For example, an oscillator can generate an oscillation signal and provide the oscillation signal to various circuits which require oscillation signals. However, oscillators in some related approaches cannot start quickly and have low reliability.

### SUMMARY

Some aspects of the present disclosure are to provide an oscillator. The oscillator includes a logic circuit and an oscillation circuit. The logic circuit is configured to receive an enable signal and a feedback signal and generate a first control signal according to the enable signal and the feedback signal. The oscillation circuit is coupled to the logic circuit and is configured to generate the feedback signal and an oscillation output signal according to the first control signal.

Some aspects of the present disclosure are to provide an operation method of an oscillator. The operation method includes following operations: receiving, by a logic circuit, an enable signal and a feedback signal; generating, by the logic circuit, a first control signal according to the enable signal and the feedback signal; and generating, by an oscillation circuit, the feedback signal and an oscillation output signal according to the first control signal.

### BRIEF DESCRIPTION OF THE DRAWINGS

The disclosure can be more fully understood by reading the following detailed description of the embodiment, with reference made to the accompanying drawings as follows:

FIG. 1 is a schematic diagram of an oscillator according to some embodiments of the present disclosure.

FIG. 2 is a waveform diagram of the oscillator in FIG. 1 according to some embodiments of the present disclosure.

FIG. 3 is a schematic diagram of an oscillator according to some embodiments of the present disclosure.

FIG. 4 is a waveform diagram of the oscillator in FIG. 3 according to some embodiments of the present disclosure.

FIG. 5 is a flow diagram of an operation method of an oscillator according to some embodiments of the present disclosure.

### DETAILED DESCRIPTION

In the present disclosure, "connected" or "coupled" may refer to “electrically connected” or “electrically coupled.” "Connected" or "coupled" may also refer to operations or actions between two or more elements.

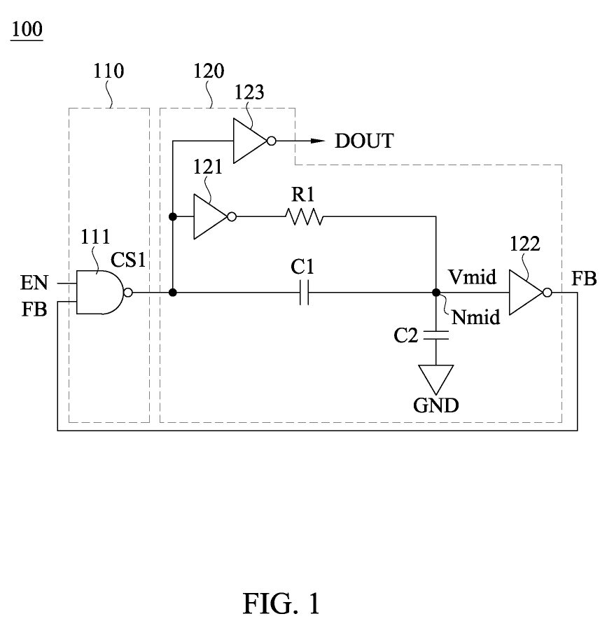

Reference is made to FIG. 1. FIG. 1 is a schematic diagram of an oscillator 100 according to some embodiments of the present disclosure.

As illustrated in FIG. 1, the oscillator 100 includes a logic circuit 110 and an oscillation circuit 120. The oscillation circuit 120 is coupled to the logic circuit 110. In one embodiment, the oscillator 100 can be applied to an integrated circuit (chip), and the oscillator 100 generates an oscillation signal and provides the oscillation signal to other circuits in the integrated circuit.

The logic circuit 110 is configured to receive an enable signalEN and a feedback signal FB, and generates a control signal CS1 according to the enable signal EN and the feedback signal FB. In one embodiment, the enable signal EN is generated by a control circuit (not shown) in an integrated circuit and is transmitted to the logic circuit 110 by the control circuit.

As illustrated in FIG. 1, the logic circuit 110 includes a NAND gate 111. The NAND gate 111 performs a NAND operation on the enable signal EN and the feedback signal FB to generate a control signal CS1.

The oscillation circuit 120 is configured to generate the feedback signal FB and an oscillation output signal DOUT according to the control signal CS1.

As illustrated in FIG. 1, the oscillation circuit 120 includes a resistor R1, a capacitor C1, a capacitor C2, an inverter 121, an inverter 122, and an inverter 123.

The resistor R1 is coupled between the NAND gate 111 in the logic circuit 110 and a relay node Nmid. The capacitor C1 is coupled between the NAND gate 111 in the logic circuit 110 and the relay node Nmid. A relay voltage Vmid is generated at the relay node Nmid. The capacitor C2 is coupled between the relay node Nmid and a ground terminal GND. The inverter 121 is coupled between the NAND gate 111 and the resistor R1. The inverter 122 is coupled to the relay node Nmid. The inverter 122 performs an inversion operation on the relay voltage Vmid to generate the feedback signal FB and feeds the feedback signal FB back to the NAND gate 111. The inverter 123 is coupled to the NAND gate 111 and performs an inversion operation on the control signal CS1 to generate the oscillation output signal DOUT.

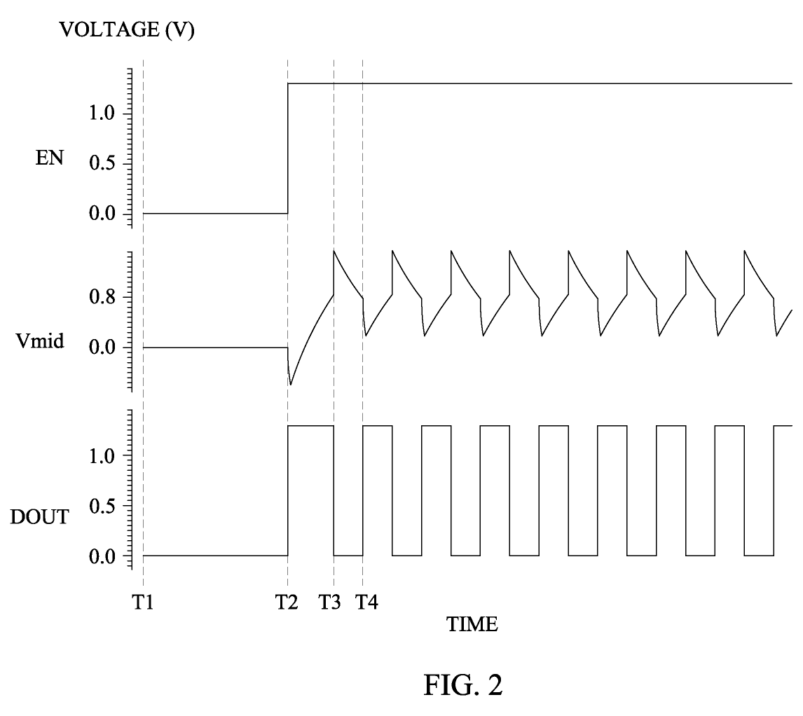

References are made to FIG. 1 and FIG. 2. FIG. 2 is a waveform diagram of the oscillator 100 in FIG. 1 according to some embodiments of the present disclosure. It is noted that the voltage values in FIG. 2 are only examples but the present disclosure is not limited thereto.

At a time point T1, the enable signal EN has a logic value of 0. At this time, the control signal CS1 has a logic value of 1. Since the control signal CS1 has the logic value of 1, an output terminal of the inverter 121 has the logic value of 0. Accordingly, the relay voltage Vmid has the logic value of 0. Since the relay voltage Vmid has the logic value of 0, the feedback signal FB outputted from the inverter 122 has the logic value of 1. In addition, since the control signal CS1 has the logic value of 1, the oscillation output signal DOUT outputted from the inverter 123 has the logic value of 0.

At a time point T2, the enable signal EN changes from the logic value of 0 to the logic value of 1. Since both of the enable signal EN and the feedback signal FB have the logic value of 1, the control signal CS1 changes from the logic value of 1 to the logic value of 0. The change of the logic value of the control signal CS1 is coupled to the relay node Nmid through the capacitor C1. Accordingly, the relay voltage Vmid decreases significantly (to a negative value). In addition, since the control signal CS1 changes from the logic value of 1 to the logic value of 0, the oscillation output signal DOUT outputted from the inverter 123 changes from the logic value of 0 to the logic value of 1.

During a time interval between the time point T2 and a time point T3, since the control signal CS1 changes from the logic value of 1 to the logic value of 0, the output terminal of the inverter 121 changes from the logic value of 0 to the logic value of 1 and charges the relay node Nmid through the resistor R1. Accordingly, the relay voltage Vmid increases gradually. Since the relay voltage Vmid has not yet increased to a threshold value of the inverter 122, the feedback signal FB outputted from the inverter 122 maintains the logic value of 1. The oscillation output signal DOUT maintains the logic value of 1.

At the time point T3, since the relay voltage Vmid increases to the threshold value of the inverter 122, the feedback signal FB outputted from the inverter 122 changes from the logic value of 1 to the logic value of 0. Since the enable signal EN has the logic value of 1 and the feedback signal FB has the logic value of 0, the control signal CS1 changes from the logic value of 0 to the logic value of 1. The change of the logic value of the control signal CS1 is coupled to the relay nodeNmid through the capacitor C1. Accordingly, the relay voltageVmid increases significantly. In addition, since the control signal CS1 changes from the logic value of 0 to the logic value of 1, the oscillation output signal DOUT outputted from the inverter 123 changes from the logic value of 1 to the logic value of 0.

During a time interval between the time point T3 and a time point T4, the relay voltage Vmid starts decreasing (discharging). The oscillation output signal DOUT maintains the logic value of 0.

At the time point T4, since the relay voltage Vmid decreases to the threshold value of the inverter 122, the feedback signal FB outputted from the inverter 122 changes from the logic value of 0 to the logic value of 1. Since both of the enable signal EN and the feedback signal FB have the logic value of 1, the control signal CS1 changes from the logic value of 1 to the logic value of 0. The change of the logic value of the control signal CS1 is coupled to the relay node Nmid through the capacitor C1. Accordingly, the relay voltage Vmid decreases significantly. In addition, since the control signal CS1 changes from the logic value of 1 to the logic value of 0, the oscillation output signal DOUT outputted from the inverter 123 changes from the logic value of 0 to the logic value of 1.

There are similar operations in following time period, so the oscillation output signal DOUT is a signal with a specific oscillation frequency. The oscillation frequency of the oscillation output signal DOUT is approximately determined by a time constant of the resistor R1 and a voltage divider ratio of the capacitor C1 and the capacitor C2.

In addition, the capacitor C1 and the capacitor C2 can form a voltage divider circuit to achieve voltage dividing effect. Thus, this can reduce the voltage swing of the of the relay voltage Vmid to avoid overvoltage issues.

In some related approaches, there is no enable signal in the oscillator, so it takes an uncertain period of time at the beginning of operation to stabilize the oscillator period of the oscillation signal. In addition, the voltage swing of the relay voltage in the current architecture is larger such that the electronic components connected in series are prone to overvoltage thereby reducing reliability.

Compared to the aforementioned related approaches, in the present disclosure, the enable signal EN can define the initial state of each node at first and stabilize the oscillator period of the oscillation output signal DOUT quickly at the beginning of operation. For example, the oscillation output signal DOUT generated by the oscillator 100 becomes stable in the second oscillation cycle. In other words, the second pulse of the oscillation output signal DOUT in FIG. 2 and the subsequent pulses have approximately same pulse width.

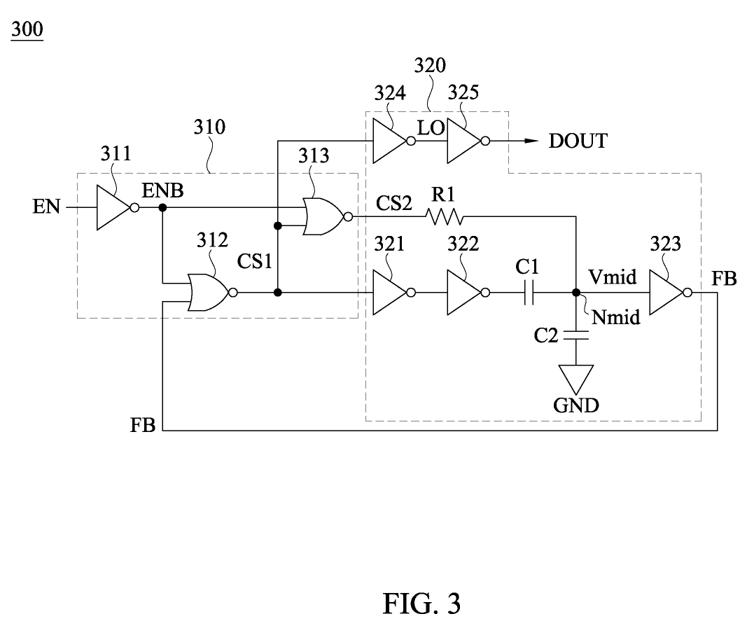

Reference is made to FIG. 3. FIG. 3 is a schematic diagram of an oscillator 300 according to some embodiments of the present disclosure.

As illustrated in FIG. 3, the oscillator 300 includes a logic circuit 310 and an oscillation circuit 320. The oscillation circuit 320 is coupled to the logic circuit 310.

The logic circuit 310 is configured to receive the enable signal EN and the feedback signal FB, and generates a control signal CS1 according to the enable signal EN and the feedback signal FB.

As illustrated in FIG. 3, the logic circuit 310 includes an inverter 311, a NOR gate 312, and a NOR gate 313. The inverter 311 performs an inversion operation on the enable signal EN to generate an inversion enable signal ENB. The NOR gate 312 performs a NOR operation on the enable signal ENB and the feedback signal FB to generate the control signal CS1. The NOR gate 313 performs a NOR operation on the inversion enable signal ENB and the control signal CS1 to generate a control signal CS2 to the relay node Nmid.

The oscillation circuit 320 is configured to generate the feedback signal FB and the oscillation output signal DOUT according to the control signal CS1.

As illustrated in FIG. 3, the oscillation circuit 320 includes a resistor R1, a capacitor C1, a capacitor C2, an inverter 321, an inverter 322, an inverter 323, an inverter 324, and an inverter 325.

The resistor R1 is coupled between the NOR gate 313 in the logic circuit 310 and the relay node Nmid. The capacitor C1 is coupled between the NOR gate 313 in the logic circuit 310 and the relay node Nmid. The relay voltage Vmid is generated at the relay node Nmid. The capacitor C2 is coupled between the relay node Nmid and the ground terminal GND. The inverter 321 is coupled to the NOR gate 312. The inverter 322 is coupled between the inverter 321 and the capacitor C1. The inverter 323 is coupled to the relay node Nmid and performs an inversion operation on the relay voltage Vmid to generate the feedback signal FB and feeds the feedback signal FB back to the NOR gate 312. The inverter 324 is coupled to the NOR gate 312 and performs an inversion operation on the control signal CS1 to generate an oscillation signal LO. The inverter 325 is coupled to the inverter 324 and performs an inversion operation on the oscillation signal LO to generate the oscillation output signal DOUT.

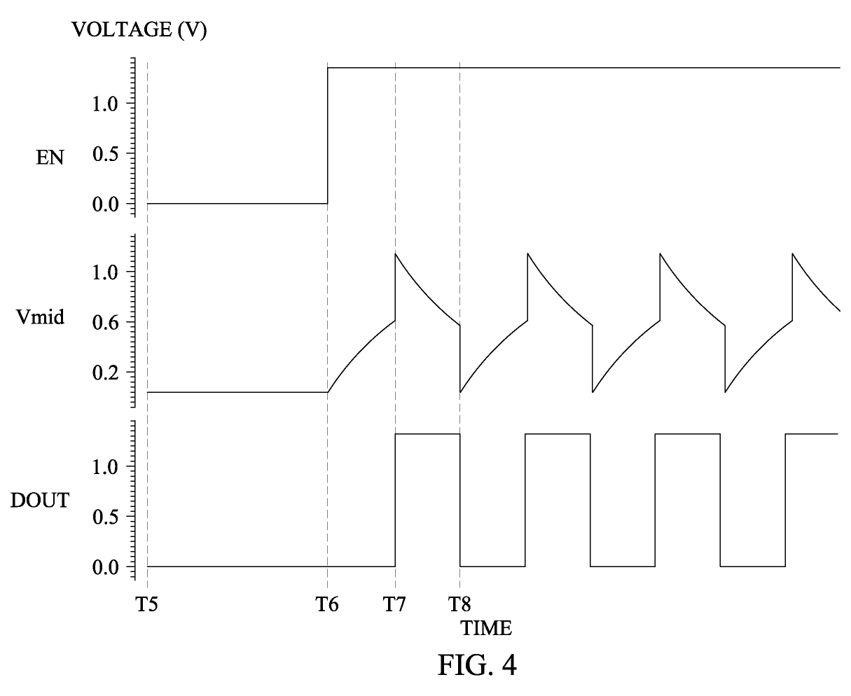

References are made to FIG. 3 and FIG. 4. FIG. 4 is a waveform diagram of the oscillator 300 in FIG. 3 according to some embodiments of the present disclosure. It is noted that the voltage values in FIG. 4 are only examples but the present disclosure is not limited thereto.

At a time point T5, the enable signal EN has the logic value of 0. At this time, the inversion enable signal ENB has the logic value of 1. Since the inversion enable signal ENB has the logic value of 1, the control signal CS2 has the logic value of 0. Accordingly, the relay voltage Vmid has the logic value of 0. Since the relay voltage Vmid has the logic value of 0, the feedback signalFB outputted from the inverter 323 has the logic value of 1. Since both of the inversion enable signal ENB and the feedback signal FB have the logic value of 1, the control signal CS1 has the logic value of 0. Since the control signal CS1 has the logic value of 0, the oscillation signalLO outputted from the inverter 324 has the logic value of 1. Since the oscillation signalLO has the logic value of 1, the oscillation output signal DOUT outputted from the inverter 325 has the logic value of 0.

During a time interval between the time point T6 and a time point T7, the enable signal EN changes from the logic value of 0 to the logic value of 1. At this time, the inversion enable signal ENB changes from the logic value of 1 to the logic value of 0. Since the inversion enable signal ENB has the logic value of 0 and the feedback signal FB has the logic value of 1, the control signal CS1 maintains the logic value of 0. Since the control signal CS1 maintains the logic value of 0, an output terminal of the inverter 321 maintains the logic value of 1 and an output terminal of the inverter 322 maintains the logic value of 0. In addition, since both of the inversion enable signal ENB and the control signal CS1 have the logic value of 0, the control signal CS2 changes from the logic value of 0 to the logic value of 1 and charges the relay node Nmid through the resistor R1. Accordingly, the relay voltage Vmid increases gradually. Since the relay voltage Vmid has not yet increased to a threshold value of the inverter 323, the feedback signal FB outputted from the inverter 323 still has the logic value of 1. The oscillation output signal DOUT maintains the logic value of 0.

At a time point T7, since the relay voltage Vmid increases to the threshold value of the inverter 323, the feedback signal FB outputted from the inverter 323 changes from the logic value of 1 to the logic value of 0. Since both of the inversion enable signal ENB and the feedback signal FB have the logic value of 0, the control signal CS1 changes from the logic value of 0 to the logic value of 1. Since the control signal CS1 changes from the logic value of 0 to the logic value of 1, the output terminal of the inverter 321 changes from the logic value of 1 to the logic value of 0 and the output terminal of the inverter 322 changes from the logic value of 0 to the logic value of 1. The change of the logic value of the output terminal of the inverter 322 is coupled to the relay node Nmid through the capacitor C1. Accordingly, the relay voltage Vmid increases significantly. In addition, since the control signal CS1 changes from the logic value of 0 to the logic value of 1, the oscillation signal LO outputted from the inverter 324 changes from the logic value of 1 to the logic value of 0 and the oscillation output signal DOUT outputted from the inverter 325 changes from the logic value of 0 to the logic value of 1.

During a time interval between the time point T7 and a time point T8, the relay voltage Vmid starts decreasing (discharging). The oscillation output signal DOUT maintains the logic value of 1.

At the time point T8, since the relay voltage Vmid decreases to the threshold value of the inverter 323, the feedback signal FB outputted from the inverter 323 changes from the logic value of 0 to the logic value of 1. Since the inversion enable signal ENB has the logic value of 0 and the feedback signal FB has the logic value of 1, the control signal CS1 changes from the logic value of 1 to the logic value of 0. Since the control signal CS1 changes from the logic value of 1 to the logic value of 0, the output terminal of the inverter 321 changes from the logic value of 0 to the logic value of 1 and the output terminal of the inverter 322 changes from the logic value of 1 to the logic value of 0. The change of logic value of the output terminal of the inverter 322 is coupled to the relay node Nmid through the capacitor C1. Accordingly, the relay voltage Vmid decreases significantly. In addition, since the control signal CS1 changes from the logic value of 1 to the logic value of 0, the oscillation signal LO outputted from the inverter 324 changes from the logic value of 0 to the logic value of 1 and the oscillation output signal DOUT outputted from the inverter 325 changes from the logic value of 1 to the logic value of 0.

There are similar operations in following time period, so the oscillation output signal DOUT is a signal with a specific oscillation frequency. The oscillation frequency of the oscillation output signal DOUT is approximately determined by a time constant of the resistor R1 and a voltage divider ratio of the capacitor C1 and the capacitor C2.

In addition, the capacitor C1 and the capacitor C2 can form a voltage divider circuit to achieve voltage dividing effect. Thus, this can reduce the voltage swing of the of the relay voltage Vmid to avoid overvoltage issues.

Compared to the oscillator 100 in FIG. 1, the oscillation output signal DOUT generated by the oscillator 300 becomes stable in the first oscillation cycle. In other words, the first pulse of the oscillation output signalDOUT in FIG. 4 and the subsequent pulses have approximately same pulse width.

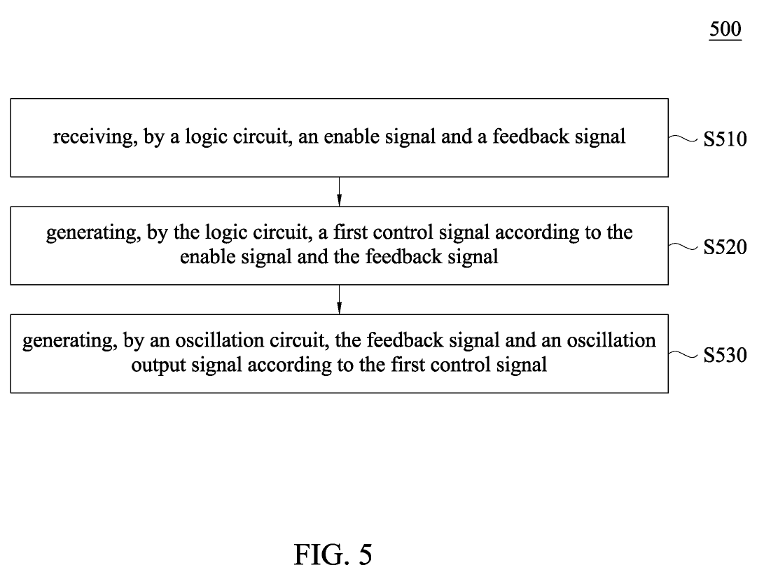

Reference is made to FIG. 5. FIG. 5 is a flow diagram of an operation method 500 of an oscillator according to some embodiments of the present disclosure.

As illustrated in FIG. 5, the operation method 500 includes operation S510, operation S520, and operation S530.

In some embodiments, the operation method 500 can be implemented to the oscillator 100 in FIG. 1 or implemented to the oscillator 300 in FIG. 3.

In operation S510, the logic circuit 110 or the logic circuit 310 receives the enable signal EN and the feedback signal FB. In some embodiments, the feedback signal FB is fed back to the logic circuit 110 or the logic circuit 310 from the oscillation circuit 120 or the oscillation circuit 320.

In operation S520, the logic circuit 110 or the logic circuit 310 generates the control signal CS1 according to the enable signal EN and the feedback signal FB. In some embodiments, the logic circuit 110 or the logic circuit 310 includes one or more logic gates. These logic gates can perform corresponding logic operations on the enable signal EN and the feedback signal FB to generate the control signal CS1.

In operation S530, the oscillation circuit 120 or the oscillation circuit 320 generates the feedback signal FB and the oscillation output signal DOUT according to the control signal CS1. In some embodiments, the oscillation circuit 120 or the oscillation circuit 320 includes one or more passive components and one or more logic gates. These logic gates can perform corresponding logic operations on the control signal CS1 to generate the oscillation output signal DOUT.

Other details about operation S510, operation S520, and operation S530 are described in aforementioned embodiments, so they are not described herein again.

As described above, in the present disclosure, the enable signal can define the initial state of each node at first and stabilize the oscillator period of the oscillation output signal quickly at the beginning of operation. Accordingly, the oscillator can start quickly and has high reliability.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An oscillator, comprising:
a logic circuit configured to receive an enable signal and a feedback signal and generate a first control signal according to the enable signal and the feedback signal; and
an oscillation circuit coupled to the logic circuit and configured to generate the feedback signal and an oscillation output signal according to the first control signal.

2. The oscillator of claim 1, wherein the oscillation circuit comprises:
a first resistor coupled between the logic circuit and a relay node;
a first capacitor coupled between the logic circuit and the relay node, wherein a relay voltage is generated at the relay node; and
a second capacitor coupled between the relay node and a ground terminal.

3. The oscillator of claim 2, wherein the logic circuit comprises:
a NAND gate configured to perform a NAND operation on the enable signal and the feedback signal to generate the first control signal.

4. The oscillator of claim 3, wherein the oscillation circuit further comprises:
a first inverter coupled between the NAND gate and the first resistor.

5. The oscillator of claim 4, wherein the oscillation circuit further comprises:
a second inverter coupled to the relay node and configured to perform a first inversion operation on the relay voltage to generate the feedback signal.

6. The oscillator of claim 5, wherein the oscillation circuit further comprises:
a third inverter coupled to the NAND gate and configured to perform a second inversion operation on the first control signal to generate the oscillation output signal.

7. The oscillator of claim 2, wherein the logic circuit comprises:
a first inverter configured to perform a first inversion operation on the enable signal to generate an inversion enable signal;
a first NOR gate configured to perform a first NOR operation on the inversion enable signal and the feedback signal to generate the first control signal; and
a second NOR gate configured to perform a second NOR operation on the inversion enable signal and the first control signal to generate a second control signal to the relay node.

8. The oscillator of claim 7, wherein the oscillation circuit comprises:
a second inverter coupled to the first NOR gate; and
a third inverter coupled between the second inverter and the first capacitor.

9. The oscillator of claim 8, wherein the oscillation circuit further comprises:
a fourth inverter coupled to the relay node and configured to perform a second inversion operation on the relay voltage to generate the feedback signal.

10. The oscillator of claim 9, wherein the oscillation circuit further comprises:
a fifth inverter coupled to the first NOR gate and configured to perform a third inversion operation on the first control signal to generate an oscillation signal; and
a sixth inverter coupled to the fifth inverter and configured to perform a fourth inversion operation on the oscillation signal to generate the oscillation output signal.

11. An operation method of an oscillator, comprising:
receiving, by a logic circuit, an enable signal and a feedback signal;
generating, by the logic circuit, a first control signal according to the enable signal and the feedback signal; and
generating, by an oscillation circuit, the feedback signal and an oscillation output signal according to the first control signal.

12. The operation method of claim 11, wherein the oscillation circuit comprises:
a first resistor coupled between the logic circuit and a relay node;
a first capacitor coupled between the logic circuit and the relay node, wherein a relay voltage is generated at the relay node; and
a second capacitor coupled between the relay node and a ground terminal.

13. The operation method of claim 12, further comprising:
performing, by a NAND gate in the logic circuit, a NAND operation on the enable signal and the feedback signal to generate the first control signal.

14. The operation method of claim 13, wherein the oscillation circuit further comprises:
a first inverter coupled between the NAND gate and the first resistor.

15. The operation method of claim 14, further comprising:
performing, by a second inverter in the oscillation circuit, a first inversion operation on the relay voltage to generate the feedback signal.

16. The operation method of claim 15, further comprising:
performing, by a third inverter in the oscillation circuit, a second inversion operation on the first control signal to generate the oscillation output signal.

17. The operation method of claim 12, further comprising:
performing, by a first inverter in the logic circuit, a first inversion operation on the enable signal to generate an inversion enable signal;
performing, by first NOR gate in the logic circuit, a first NOR operation on the inversion enable signal and the feedback signal to generate the first control signal; and
performing, by a second NOR gate in the logic circuit, a second NOR operation on the inversion enable signal and the first control signal to generate a second control signal to the relay node.

18. The operation method of claim 17, wherein the oscillation circuit comprises:
a second inverter coupled to the first NOR gate; and
a third inverter coupled between the second inverter and the first capacitor.

19. The operation method of claim 18, further comprising:
performing, by a fourth inverter in the oscillation circuit, a second inversion operation on the relay voltage to generate the feedback signal.

20. The operation method of claim 19, further comprising:
performing, by a fifth inverter in the oscillation circuit, a third inversion operation on the first control signal to generate an oscillation signal; and
performing, by a sixth inverter in the oscillation circuit, a fourth inversion operation on the oscillation signal to generate the oscillation output signal.
